(19) United States
(12) Patent Application Publication
(10) Pub. No.: US 2025/0245496 A1
(43) Pub. Date: Jul. 31, 2025

(54) HOMOGENEOUS OPTOELECTRONIC RESERVOIR COMPUTING SYSTEM BASED ON NITROGEN-DOPED GE-SB-TE MATERIAL

(71) Applicant: HUAZHONG UNIVERSITY OF SCIENCE AND TECHNOLOGY, Hubei (CN)

(72) Inventors: Xiaomin CHENG, Hubei (CN); Peng ZHAO, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 18/829,143

(22) Filed: Sep. 9, 2024

Related U.S. Application Data
(63) Continuation of application No. PCT/CN2024/078697, filed on Feb. 27, 2024.

(30) Foreign Application Priority Data
Jan. 31, 2024 (CN) 202410137589.3

(51) Int. Cl. G06N 3/063; C01B 19/00

(52) U.S. Cl. CPC G06N 3/063; C01B 19/002; G11C 13/04; H10F 30/00; H10F 77/1215; C01P 2006/40; C01P 2006/60

(57) ABSTRACT

A homogeneous optoelectronic reservoir computing system based on a nitrogen-doped Ge—Sb—Te material includes an optoelectronic reservoir layer and a readout layer connected to each other; the optoelectronic reservoir layer includes multiple optical synaptic devices based on nitrogen-doped Ge—Sb—Te material, and the optical synaptic devices realize perception and nonlinear response of image light signals based on the photoconductive effect of a single light pulse and the paired-pulse facilitation effect under a double light pulse; the readout layer includes multiple electrical synaptic devices based on the nitrogen-doped Ge—Sb—Te material, and the electrical synaptic devices realize linear response and image recognition of output signals of the optoelectronic reservoir layer based on linearity, symmetry long-term potentiation function, and long-term depression function. In the system of the disclosure, both the reservoir layer and the readout layer use devices based on the same material.

### CROSS-REFERENCE TO RELATED APPLICATION

This application is a continuation of international application of PCT application serial no. PCT/CN2024/078697, filed on Feb. 27, 2024, which claims the priority benefit of China application no. 202410137589.3, filed on Jan. 31, 2024. The entirety of each of the above-mentioned patent applications is hereby incorporated by reference herein and made a part of this specification.

### BACKGROUND

### Technical Field

The disclosure belongs to the field of micro-nanoelectronic technology, and more specifically, relates to a homogeneous optoelectronic reservoir computing system based on a nitrogen-doped Ge—Sb—Te material.

### Description of Related Art

The visual system is the most important sensory system of human beings. Vision accounts for the vast majority of the information that people receive from the outside world and can strongly influence cognition, decision-making, emotions, and even subconscious activities of people. Therefore, developing electronic devices with visual functions is an important step toward achieving bionic functions.

In conventional machine vision systems, visual information is captured by image sensors and converted into digital signals for use by storage units and subsequent computing units. The separation of processor and memory in conventional computing units based on the von Neumann architecture leads to huge delays and energy consumption during matrix multiplication processing, hindering delay-sensitive applications such as driverless cars, robots or industrial manufacturing, thereby it is difficult to meet the needs of instant interactive systems. Replacing the von Neumann architecture with an integrated storage and computing architecture requires additional digital-to-analog conversion (DAC). In addition, the transmission of redundant data of the image sensor also causes higher power consumption.

The human visual system uses sensory neurons to detect analog light signals and perform image preprocessing, and then to perform further visual signal processing in the visual cortex of the human brain. In this process, full analog processing and reduced data movement achieve low latency and high energy efficiency. Inspired by the above, the artificial neural network based on the optoelectronic neuromorphic architecture has the advantages of in-sensor computing and in-memory computing, which can further improve the perception and signal processing efficiency of machine vision. In various artificial neural network architectures, reservoir computing has the advantage of only requiring training of the readout layer of the network and has been shown to be suitable for processing complex spatiotemporal data with minimal training cost. The reservoir computing architecture includes a reservoir layer and a readout layer. Since the reservoir layer (mapping the input time series signal to a high-dimensional feature space) and the readout layer (simple linear processing) have different functions, the currently proposed optoelectronic reservoir computing systems all use different materials to implement the reservoir layers and readout layers respectively, which poses a challenge to the system integration and process compatibility.

### SUMMARY

In view of the above defects or improvement needs of the related art, the disclosure provides a homogeneous optoelectronic reservoir computing system based on a nitrogen-doped Ge—Sb—Te material, and the purpose thereof is to solve the technical problem that the materials of the reservoir layer and the readout layer in the existing optoelectronic reservoir computing system are different, which leads to low integration and process compatibility.

To achieve the above-mentioned purpose, the disclosure provides a homogeneous optoelectronic reservoir computing system based on a nitrogen-doped Ge—Sb—Te material, including an optoelectronic reservoir layer and a readout layer connected to each other.

The optoelectronic reservoir layer includes a plurality of optical synaptic devices based on the nitrogen-doped Ge—Sb—Te material, and the optical synaptic devices realize perception and nonlinear response of an image light signal based on photoconductive effect of a single light pulse and paired-pulse facilitation effect under a double light pulse.

The readout layer includes a plurality of electrical synaptic devices based on the nitrogen-doped Ge—Sb—Te material, and the electrical synaptic devices realize linear response and image recognition of an output signal of the optoelectronic reservoir layer based on linearity, symmetry long-term potentiation function, and long-term depression function.

Preferably, the optical synaptic device includes a photosensitive layer, a left electrode layer, and a right electrode layer; the left electrode layer and the right electrode layer are formed on the photosensitive layer and are parallel to each other; the photosensitive layer has a thickness of 5 nm to 500 nm, and the left electrode layer and the right electrode layer have a thickness of 3 nm to 500 nm; a distance between the left electrode layer and the right electrode layer is 1 um to 500 um.

Preferably, a material of the left electrode layer and the right electrode layer is Al, Ag, Cu, Ti₃W₇, Pt, Au, W, Ti, or TiN.

Preferably, the photosensitive layer is the nitrogen-doped Ge—Sb—Te material, a general formula thereof is Nₓ(Ge—Sb—Te)₁₋ₓ; a base material of Ge—Sb—Te is a compound composed of one or more of Ge, Sb, and Te elements, and a nitrogen doping ratio is 0<x≤10%.

Preferably, the electrical synaptic device includes a lower electrode, an isolation layer, a function layer, and an upper electrode; the isolation layer is located above the lower electrode, a through hole is opened inside the isolation layer, and the through hole is filled with the function layer; the function layer is located between the lower electrode and the upper electrode; a thickness of the upper electrode and the lower electrode is 5 nm to 500 nm, a thickness of the function layer is 5 nm to 500 nm, a thickness of the isolation layer is 5 nm to 500 nm, and a radius of the through hole of the isolation layer is 5 nm to 1000 nm.

Preferably, a material of the upper electrode and the lower electrode is Al, Ag, Cu, Ti₃W₇, Pt, Au, W, Ti, or TiN.

Preferably, a material of the isolation layer is Si₃N₄, SiO2, SiC, or (ZnS)_{y}(SiO2)_{100-y}, and y is an integer greater than 0 and less than 100.

Preferably, the function layer is the nitrogen-doped Ge—Sb—Te material, and a general formula thereof is N_{z}(Ge—Sb—Te)_{1-z}; a base material of Ge—Sb—Te is a compound composed of one or more of Ge, Sb, and Te elements, and a nitrogen doping ratio is 0<z≤10%.

In general, the above technical solutions conceived by the disclosure have the following beneficial effects compared with the related art:

(1) Compared with the conventional machine vision system with separated sensing, storage, and computing, the disclosure adopts a bionic approach to achieve the visual function similar to biological organisms, and uses an optoelectronic reservoir computing system to realize the detection of optical signals and the recognition and processing of information, which has the technical advantages of low latency and high energy efficiency.

(2) Compared with the existing heterogeneous reservoir computing system, in the optoelectronic reservoir computing system of the disclosure, the reservoir layer and the readout layer use devices based on the same material, realizing a homogeneous optoelectronic reservoir computing system with higher system integration and process compatibility.

(3) The disclosure uses the nitrogen-doped Ge—Sb—Te material to prepare optical synaptic devices and electrical synaptic devices respectively, in which the optical synaptic device based on the nitrogen-doped Ge—Sb—Te material has a photoconductive effect of a single light pulse and a paired-pulse facilitation effect under a double light pulse, realizing perception and processing functions of image signals; the electrical synaptic device based on the nitrogen-doped Ge—Sb—Te material has high linearity, high symmetry long-term potentiation (LTP) and long-term depression (LTD) functions, which realizes the storage and computation of the output signal of the optoelectronic reservoir layer; compared with existing synaptic devices based on sulfur compounds, the physical properties are richer, and the functions achieved are more comprehensive.

### BRIEF DESCRIPTION OF THE DRAWINGS

FIG. 1 is a schematic structural diagram of an N—Ge₁Sb₄Te₇ optical synaptic device provided in an embodiment of the disclosure.

FIG. 2 is a time-dependent normalized photoresponse curve of the N—Ge₁Sb₄Te₇ optical synaptic device under light stimulation provided in an embodiment of the disclosure.

FIG. 3 is a diagram showing a paired-pulse facilitation effect under a double pulse of the N—Ge₁Sb₄Te₇ optical synaptic device provided in an embodiment of the disclosure.

FIG. 4 is a schematic structural diagram of an electrical synaptic device provided in an embodiment of the disclosure.

FIG. 5 is a long-term potentiation/depression measurement diagram of the N—Ge₁Sb₄Te₇ electrical synaptic device provided in an embodiment of the disclosure.

FIG. 6 is a schematic diagram of a homogeneous optoelectronic reservoir computing system based on N—Ge₁Sb₄Te₇ provided in an embodiment of the disclosure.

FIG. 7 is a schematic diagram showing how a recognition accuracy of the homogeneous optoelectronic reservoir computing system based on N—Ge₁Sb₄Te₇ provided in an embodiment of the disclosure varies with a quantity of training iterations.

### DESCRIPTION OF THE EMBODIMENTS

In order to make the purposes, technical solutions, and advantages of the disclosure more comprehensible, the disclosure is further described in detail below together with the accompanying drawings and embodiments. It should be understood that the specific embodiments described herein are only used to explain the disclosure and the embodiments are not used to limit the disclosure.

It is understood that in the description of the disclosure, the terms, for example, “upper”, “lower”, “vertical”, “horizontal”, indicate positions or positional relationships based on the positions or positional relationships shown in the accompanying drawings, which is only for the convenience of describing the disclosure and simplifying the description, and does not indicate or imply that the devices or elements referred to have to have a specific orientation or be constructed and operate in a specific orientation, and thus should not be understood as limiting the disclosure. Furthermore, the terms “first” and “second” are used for descriptive purposes only and should not be understood as indicating or implying relative importance.

In addition, many specific details of the disclosure are described below, such as device structure, material, size, processing technology and technique, so as to more clearly understand the disclosure. However, as will be appreciated by persons skilled in the art, the disclosure may be implemented without following the specific details. Unless otherwise specified below, each part of the device may be made of materials known to persons skilled in the art, or materials with similar functions to be developed in the future may be used.

It should be understood that the various numerical symbols involved in the embodiments of the disclosure are only used for the convenience of description and are not used to limit the scope of the embodiments of the disclosure.

Next, the technical solutions provided in the embodiments of the disclosure are introduced.

### Example 1A

Example 1A of the disclosure provides an N—Ge₁Sb₄Te₇ optical synaptic device, and the specific preparation process is as follows:

1. A SiO₂/Si (100) substrate with a size of 1 cm×1 cm is selected as the substrate, the surface and back are cleaned, and dust particles and organic and inorganic impurities are removed; specifically:

a) The substrate is placed in an acetone solution, subjected to ultrasonic vibration at a power of 40 W for 10 minutes, and then rinsed with deionized water.

b) The substrate treated with acetone is subjected to ultrasonic vibration at a power of 40 W for 10 minutes in an ethanol solution and rinsed with deionized water; the surface and back are dried with high-purity N₂ gas to obtain a substrate to be sputtered.

2. An N-doped Ge₁Sb₄Te₇ photosensitive layer 1 is prepared by magnetron sputtering method, the target material is a Ge₁Sb₄Te₇ alloy target, and sputtering is performed using a DC power supply. During the sputtering process, the thickness of the N-doped Ge₁Sb₄Te₇ photosensitive layer 1 may be adjusted by adjusting the sputtering power and the sputtering time; in this embodiment, N₂: Ar=3: 40 (the doping concentration is 0.92%), the total gas pressure is 0.5 Pa, the power is 30 W, sputtering is performed for 300 s, and the thickness of the prepared photosensitive layer 1 is 100 nm.

3. Patterns of a left electrode layer 2 and a right electrode layer 3 are prepared on the photosensitive layer 1 by photolithography, and through coating, pre-baking, pre-exposure, post-baking, post-exposure, and developing processes, pattern mask layers of the left electrode layer 2 and the right electrode layer 3 are prepared and obtained.

4. The sample after photolithography is taken to prepare the left electrode layer 2 and the right electrode layer 3 by using the sputtering process; the sputtering power is 40 W, the argon ambient pressure is 0.5 Pa, the DC sputtering is performed for 700 s, and W electrodes with a thickness of 100 nm are obtained to serve as the left electrode layer 2 and the right electrode layer 3; the distance between the left electrode layer and the right electrode layer is 100 um.

5. The sample prepared by sputtering the left electrode layer 2 and the right electrode layer 3 is taken, soaked in an acetone solution for 30 minutes, peeled off the pattern mask layers of the left electrode layer 2 and the right electrode layer 3, rinsed with ethanol and deionized water, blow dried with a nitrogen gun, and the patterned left electrode layer 2 and the right electrode layer 3 are obtained.

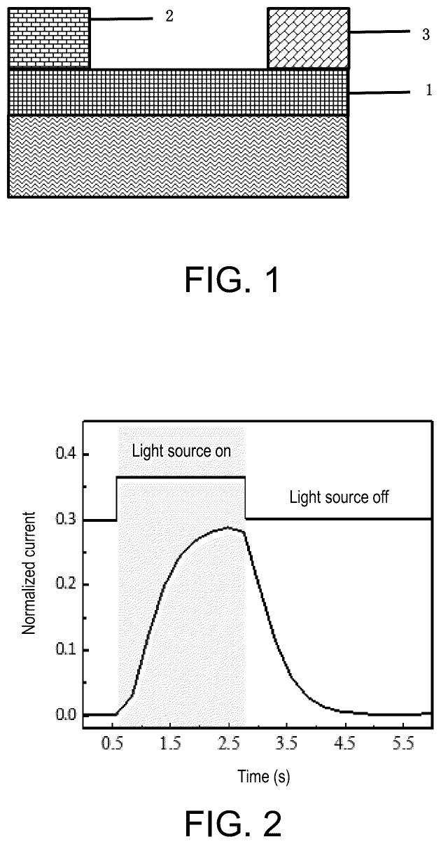

After completing the above steps, the preparation of the N—Ge₁Sb₄Te₇ optical synaptic device is completed, and the device structure is shown in FIG. 1.

### Example 1B

Example 1B of the disclosure provides an N—Ge₁Sb₄Te₇ optical synaptic device, and the specific preparation process is as follows:

1. A SiO₂/Si (100) substrate with a size of 1 cm×1 cm is selected as the substrate, the surface and back are cleaned, and dust particles and organic and inorganic impurities are removed; specifically:

a) The substrate is placed in an acetone solution, subjected to ultrasonic vibration at a power of 40 W for 10 minutes, and then rinsed with deionized water.

b) The substrate treated with acetone is subjected to ultrasonic vibration at a power of 40 W for 10 minutes in an ethanol solution and rinsed with deionized water; the surface and back are dried with high-purity N₂ gas to obtain a substrate to be sputtered.

2. An N-doped Ge₁Sb₄Te₇ photosensitive layer 1 is prepared by magnetron sputtering method, the target material is a Ge₁Sb₄Te₇ alloy target, and sputtering is performed using a DC power supply. During the sputtering process, the thickness of the N-doped Ge₁Sb₄Te₇ photosensitive layer 1 may be adjusted by adjusting the sputtering power and the sputtering time; in this embodiment, N₂: Ar=1: 40 (the doping concentration is 0.1%), the total gas pressure is 0.5 Pa, the power is 30 W, sputtering is performed for 30 s, and the thickness of the prepared photosensitive layer 1 is 5 nm.

3. Patterns of a left electrode layer 2 and a right electrode layer 3 are prepared on the photosensitive layer 1 by photolithography, and through coating, pre-baking, pre-exposure, post-baking, post-exposure, and developing processes, pattern mask layers of the left electrode layer 2 and the right electrode layer 3 are prepared and obtained.

4. The sample after photolithography is taken to prepare the left electrode layer 2 and the right electrode layer 3 by using the sputtering process; the sputtering power is 40 W, the argon ambient pressure is 0.5 Pa, the DC sputtering is performed for 50 s, and W electrodes with a thickness of 3 nm are obtained to serve as the left electrode layer 2 and the right electrode layer 3; the distance between the left electrode layer and the right electrode layer is 1 um.

5. The sample prepared by sputtering the left electrode layer 2 and the right electrode layer 3 is taken, soaked in an acetone solution for 30 minutes, peeled off the pattern mask layers of the left electrode layer 2 and the right electrode layer 3, rinsed with ethanol and deionized water, blow dried with a nitrogen gun, and the patterned left electrode layer 2 and the right electrode layer 3 are obtained.

### Example 1C

Example 1 C of the disclosure provides an N—Ge₁Sb₄Te₇ optical synaptic device, and the specific preparation process is as follows:

1. A SiO₂/Si (100) substrate with a size of 1 cm×1 cm is selected as the substrate, the surface and back are cleaned, and dust particles and organic and inorganic impurities are removed; specifically:

a) The substrate is placed in an acetone solution, subjected to ultrasonic vibration at a power of 40 W for 10 minutes, and then rinsed with deionized water.

b) The substrate treated with acetone is subjected to ultrasonic vibration at a power of 40 W for 10 minutes in an ethanol solution and rinsed with deionized water; the surface and back are dried with high-purity N₂ gas to obtain a substrate to be sputtered.

2. An N-doped Ge₁Sb₄Te₇ photosensitive layer 1 is prepared by magnetron sputtering method, the target material is a Ge₁Sb₄Te₇ alloy target, and sputtering is performed using a DC power supply. During the sputtering process, the thickness of the N-doped Ge₁Sb₄Te₇ photosensitive layer 1 may be adjusted by adjusting the sputtering power and the sputtering time; in this embodiment, N₂: Ar=10: 40 (the doping concentration is 10%), the total gas pressure is 0.5 Pa, the power is 30 W, sputtering is performed for 1200 s, and the thickness of the prepared photosensitive layer 1 is 500 nm.

3. Patterns of a left electrode layer 2 and a right electrode layer 3 are prepared on the photosensitive layer 1 by photolithography, and through coating, pre-baking, pre-exposure, post-baking, post-exposure, and developing processes, pattern mask layers of the left electrode layer 2 and the right electrode layer 3 are prepared and obtained.

4. The sample after photolithography is taken to prepare the left electrode layer 2 and the right electrode layer 3 by using the sputtering process; the sputtering power is 40 W, the argon ambient pressure is 0.5 Pa, the DC sputtering is performed for 2500 s, and W electrodes with a thickness of 500 nm are obtained to serve as the left electrode layer 2 and the right electrode layer 3; the distance between the left electrode layer and the right electrode layer is 500 um.

5. The sample prepared by sputtering the left electrode layer 2 and the right electrode layer 3 is taken, soaked in an acetone solution for 30 minutes, peeled off the pattern mask layers of the left electrode layer 2 and the right electrode layer 3, rinsed with ethanol and deionized water, blow dried with a nitrogen gun, and the patterned left electrode layer 2 and the right electrode layer 3 are obtained.

### Example 2

In Example 2 of the disclosure, a photoelectric testing system is used to test the optical performance of the N—Ge₁Sb₄Te₇ optical synaptic device.

FIG. 2 is a time-dependent normalized photo response curve of the N—Ge₁Sb₄Te₇ optical synaptic device under light pulse stimulation provided in an embodiment of the disclosure. It may be seen that light pulse stimulation triggers a significant increase in current, and the current gradually decays within a few seconds after the stimulation is eliminated, which shows that the N—Ge₁Sb₄Te₇ optical synaptic device exhibits a significant photoconductive effect.

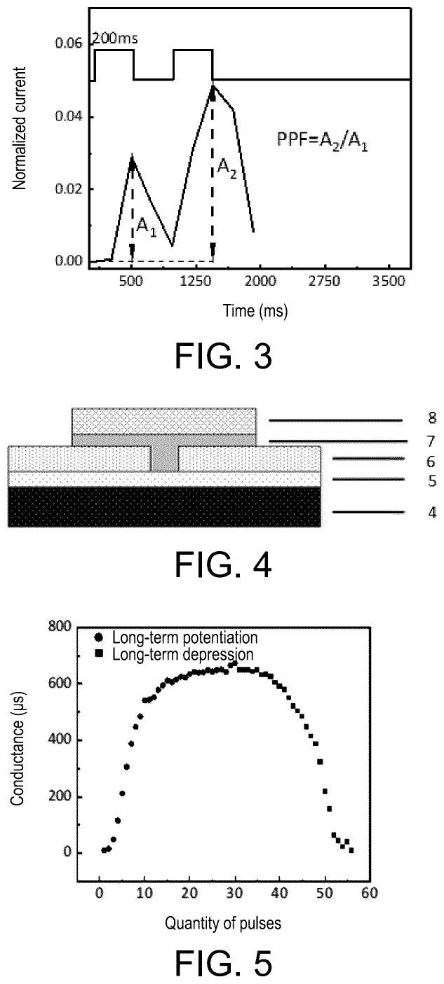

FIG. 3 is a diagram showing a paired-pulse facilitation effect under a double pulse of the N—Ge₁Sb₄Te₇ optical synaptic device provided in an embodiment of the disclosure. In FIG. 3, the width of the optical pulse is 200 ms, and the distance between two optical pulses is 200 ms. When two light pulses are applied to the N—Ge₁Sb₄Te₇ optical synaptic device sequentially, due to the coupling of excitatory postsynaptic current caused by the photoconductive effect, the excitatory postsynaptic current value of the second light pulse is higher than the first light pulse. It may be seen that the device has the potential to process complex time information.

### Example 3A

Example 3A of the disclosure provides an N—Ge₁Sb₄Te₇ electrical synaptic device, and the specific preparation process is as follows:

1. A SiO₂/Si (100) substrate with a size of 1 cm×1 cm is selected as a substrate 4, the surface and back are cleaned, and dust particles and organic and inorganic impurities are removed; specifically:

a) The substrate 4 is placed in an acetone solution, subjected to ultrasonic vibration at a power of 40 W for 10 minutes, and then rinsed with deionized water.

b) The substrate 4 treated with acetone is subjected to ultrasonic vibration at a power of 40 W for 10 minutes in an ethanol solution and rinsed with deionized water; the surface and back are dried with high-purity N₂ gas to obtain a substrate to be sputtered.

2. A Pt electrode with a thickness of 100 nm is prepared as a lower electrode 5 by the DC power sputtering method.

3. SiO₂ with a thickness of 100 nm is deposited on the Pt lower electrode 5 in Step 2 by using chemical vapor deposition to obtain an isolation layer 6.

4. Through electron beam lithography and etching processes, a through hole with a depth of 100 nm and a radius of 125 nm is formed in the isolation layer 6 in Step 3.

5. An upper electrode 8 square pattern array is formed through an overlay process.

6. An N-doped Ge₁Sb₄Te₇ function layer 7 is prepared by magnetron sputtering method, the target material is a Ge₁Sb₄Te₇ alloy target, and sputtering is performed using a DC power supply. During the sputtering process, the thickness of the N-doped Ge₁Sb₄Te₇ function layer 7 may be adjusted by adjusting the sputtering power and the sputtering time; in this embodiment, N₂: Ar=3: 40 (the doping concentration is 0.92%), the total gas pressure is 0.5 Pa, the power is 30 W, sputtering is performed for 300 s, and the thickness of the prepared N-doped Ge₁Sb₄Te₇ function layer 7 is 100 nm.

7. A Pt electrode with a thickness of 100 nm is prepared as the upper electrode 8 by the DC power sputtering method.

After completing the above steps, an array of N—Ge₁Sb₄Te₇ electrical synaptic devices is obtained on the sample, and the device structure is shown in FIG. 4.

### Example 3B

Example 3B of the disclosure provides an N—Ge₁Sb₄Te₇ electrical synaptic device, and the specific preparation process is as follows:

1. A SiO₂/Si (100) substrate with a size of 1 cm×1 cm is selected as the substrate 4, the surface and back are cleaned, and dust particles and organic and inorganic impurities are removed; specifically:

a) The substrate 4 is placed in an acetone solution, subjected to ultrasonic vibration at a power of 40 W for 10 minutes, and then rinsed with deionized water.

b) The substrate 4 treated with acetone is subjected to ultrasonic vibration at a power of 40 W for 10 minutes in an ethanol solution and rinsed with deionized water; the surface and back are dried with high-purity N₂ gas to obtain a substrate to be sputtered.

2. A Pt electrode with a thickness of 5 nm is prepared as the lower electrode 5 by the DC power sputtering method.

3. SiO₂ with a thickness of 5 nm is deposited on the Pt lower electrode 5 in Step 2 to by chemical vapor deposition to obtain the isolation layer 6.

4. Through electron beam lithography and etching processes, a through hole with a depth of 5 nm and a radius of 5 nm is formed in the isolation layer 6 in step 3.

5. An upper electrode 8 square pattern array is formed through an overlay process.

6. An N-doped Ge₁Sb₄Te₇ function layer 7 is prepared by magnetron sputtering method, the target material is a Ge₁Sb₄Te₇ alloy target, and sputtering is performed using a DC power supply. During the sputtering process, the thickness of the N-doped Ge₁Sb₄Te₇ function layer 7 may be adjusted by adjusting the sputtering power and the sputtering time; in this embodiment, N₂: Ar=1: 40 (the doping concentration is 0.1%), the total gas pressure is 0.5 Pa, the power is 30 W, sputtering is performed for 30 s, and the thickness of the prepared N-doped Ge₁Sb₄Te₇ function layer 7 is 5 nm.

7. A Pt electrode with a thickness of 5 nm is prepared as the upper electrode 8 by the DC power sputtering method.

### Example 3C

Example 3C of the disclosure provides an N—Ge₁Sb₄Te₇ electrical synaptic device, and the specific preparation process is as follows:

1. A SiO₂/Si (100) substrate with a size of 1 cm×1 cm is selected as a substrate 4, the surface and back are cleaned, and dust particles and organic and inorganic impurities are removed; specifically:

a) The substrate 4 is placed in an acetone solution, subjected to ultrasonic vibration at a power of 40 W for 10 minutes, and then rinsed with deionized water.

b) The substrate 4 treated with acetone is subjected to ultrasonic vibration at a power of 40 W for 10 minutes in an ethanol solution and rinsed with deionized water; the surface and back are dried with high-purity N₂ gas to obtain a substrate to be sputtered.

2. A Pt electrode with a thickness of 500 nm is prepared as the lower electrode 5 by the DC power sputtering method.

3. SiO₂ with a thickness of 500 nm is deposited on the Pt lower electrode 5 in Step 2 by using chemical vapor deposition to obtain the isolation layer 6.

4. Through electron beam lithography and etching processes, a through hole with a depth of 500 nm and a radius of 1000 nm is formed in the isolation layer 6 in step 3.

5. The upper electrode 8 square pattern array is formed through an overlay process.

6. An N-doped Ge₁Sb₄Te₇ function layer 7 is prepared by magnetron sputtering method, the target material is a Ge₁Sb₄Te₇ alloy target, and sputtering is performed using a DC power supply. During the sputtering process, the thickness of the N-doped Ge₁Sb₄Te₇ function layer 7 may be adjusted by adjusting the sputtering power and the sputtering time; in this embodiment, N₂: Ar=10: 40 (the doping concentration is 10%), the total gas pressure is 0.5 Pa, the power is 30 W, sputtering is performed for 1200 s, and the thickness of the prepared N-doped Ge₁Sb₄Te₇ function layer 7 is 500 nm.

7. A Pt electrode with a thickness of 500 nm is prepared as the upper electrode 8 by the DC power sputtering method.

### Example 4

Example 4 of the disclosure performs long-term potentiation (LTP)/depression (LTD) measurements on the N—Ge₁Sb₄Te₇ electrical synaptic device. As shown in FIG. 5, it may be seen that the change shape of the conductance shows good continuity with the quantity of applied pulses. In FIG. 5, the nonlinearity of the LTP part is 3.72 and the nonlinearity of the LTD part is 2.32 according to the fitting formula, which indicates that the conductance regulation of the N—Ge₁Sb₄Te₇ electrical synaptic device is highly linear. In addition, the nonlinearities of LTP and LTD are both positive, which shows that the conductance regulation is highly symmetrical.

### Example 5

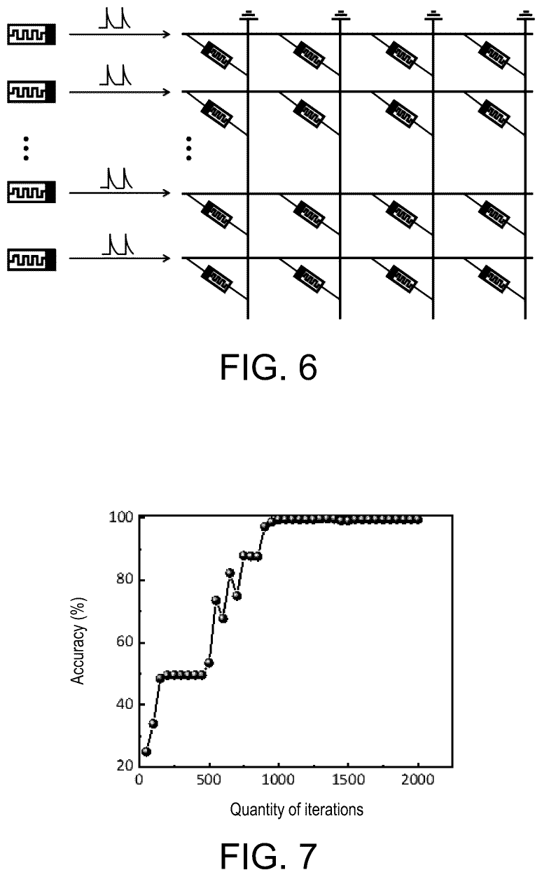

In Example 5 of the disclosure, Matlab software is used to build a homogeneous optoelectronic reservoir computing network based on N—Ge₁Sb₄Te₇. FIG. 6 is a schematic diagram of a homogeneous optoelectronic reservoir computing system based on N—Ge₁Sb₄Te₇. In the embodiment, the characteristics of N—Ge₁Sb₄Te₇ (the doping concentration is 0.92%) optical synaptic device are used as the reservoir layer in the reservoir computing network, and the characteristics of N—Ge₁Sb₄Te₇ (the doping concentration is 0.92%) electrical synaptic device are used as the readout layer in the reservoir computing network. The homogeneous optoelectronic reservoir computing network based on N—Ge₁Sb₄Te₇ is used to recognize sign language images. The drawing shows the recognition accuracy varies with a quantity of training iterations, which may be seen that after only 1,000 iterations, the accuracy can reach 99.5%, which shows that the homogeneous optoelectronic reservoir computing network based on N—Ge₁Sb₄Te₇ has the potential for practical application in artificial vision systems.

The above content is easily understood by persons skilled in the art. The above description is only preferred embodiments of the disclosure and the embodiments are not intended to limit the disclosure. Any modifications, equivalent substitutions, and improvements made within the spirit and principles of the disclosure should be included in the protection scope of the disclosure.

What is claimed is:

1. A homogeneous optoelectronic reservoir computing system based on a nitrogen-doped Ge—Sb—Te material comprising an optoelectronic reservoir layer and a readout layer connected to each other, wherein
the optoelectronic reservoir layer comprises a plurality of optical synaptic devices based on the nitrogen-doped Ge—Sb—Te material, and the optical synaptic devices realize perception and nonlinear response of an image light signal based on a photoconductive effect of a single light pulse and a paired-pulse facilitation effect under a double light pulse,
the readout layer comprises a plurality of electrical synaptic devices based on the nitrogen-doped Ge—Sb—Te material, and the electrical synaptic devices realize linear response and image recognition of an output signal of the optoelectronic reservoir layer based on linearity, a symmetry long-term potentiation function, and a long-term depression function.

2. The homogeneous optoelectronic reservoir computing system according to claim 1, wherein the optical synaptic device comprises a photosensitive layer, a left electrode layer, and a right electrode layer, the left electrode layer and the right electrode layer are formed on the photosensitive layer and are parallel to each other, the photosensitive layer has a thickness of 5 nm to 500 nm, the left electrode layer and the right electrode layer have a thickness of 3 nm to 500 nm, and a distance between the left electrode layer and the right electrode layer is 1 um to 500 um.

3. The homogeneous optoelectronic reservoir computing system according to claim 2, wherein a material of the left electrode layer and the right electrode layer is Al, Ag, Cu, Ti₃W₇, Pt, Au, W, Ti, or TiN.

4. The homogeneous optoelectronic reservoir computing system according to claim 2, wherein the photosensitive layer is the nitrogen-doped Ge—Sb—Te material, a general formula thereof is Nₓ(Ge—Sb—Te)₁₋ₓ, a base material of Ge—Sb—Te is a compound comprising one or more of Ge, Sb, and Te elements, and a nitrogen doping ratio is 0<x≤10%.

5. The homogeneous optoelectronic reservoir computing system according to claim 1, wherein the electrical synaptic device comprises a lower electrode, an isolation layer, a function layer, and an upper electrode, the isolation layer is located above the lower electrode, a through hole is opened inside the isolation layer, the through hole is filled with the function layer, the function layer is located between the lower electrode and the upper electrode, a thickness of the upper electrode and the lower electrode is 5 nm to 500 nm, a thickness of the function layer is 5 nm to 500 nm, a thickness of the isolation layer is 5 nm to 500 nm, and a radius of the through hole of the isolation layer is 5 nm to 1000 nm.

6. The homogeneous optoelectronic reservoir computing system according to claim 5, wherein a material of the upper electrode and the lower electrode is Al, Ag, Cu, Ti₃W₇, Pt, Au, W, Ti, or TiN.

7. The homogeneous optoelectronic reservoir computing system according to claim 5, wherein a material of the isolation layer is Si₃N₄, SiO2, SiC, or (ZnS)_{y}(SiO2)_{100-y}, and y is an integer greater than 0 and less than 100.

8. The homogeneous optoelectronic reservoir computing system according to claim 5, wherein the function layer is the nitrogen-doped Ge—Sb—Te material, a general formula thereof is N_{z}(Ge—Sb—Te)_{1-z}, a base material of Ge—Sb—Te is a compound comprising one or more of Ge, Sb, and Te elements, and a nitrogen doping ratio is 0<z≤10%.
